(19) United States
(12) Patent Application Publication
(10) Pub. No.: US 2011/0079284 A1
(43) Pub. Date: Apr. 7, 2011

(54) STRUCTURE AND METHOD FOR CONNECTING JUNCTION BOX TO SOLAR CELL MODULE

(76) Inventor: KAI WU, Taichung County (TW)

(21) Appl. No.: 12/896,465

(22) Filed: Oct. 1, 2010

(30) Foreign Application Priority Data
Oct. 1, 2009 (TW) 098133432

(51) Int. Cl. H01L 31/0203; H01L 31/0264; H01L 31/0272; H05K 13/00

(52) U.S. Cl. 136/259; 136/260; 136/262; 136/264; 136/265; 29/592.1

(57) ABSTRACT

In a structure and method for connecting junction box to solar cell module, at least one support pin is embedded in the laminated layers of the solar cell module. The support pin includes at least a plug section, a support section and a stop section. The support section is embedded in the laminated layers of the solar cell module and can therefore provide support strength to the junction box. The stop section is pressed against an end surface of the solar cell module to enable a limiting and lateral supporting effect. The plug section is exposed from a layer of fixing sealant applied on the end surface of the solar cell module for plugging in and accordingly holding to a socket section of the junction box, protecting the junction box against separating from the solar cell module before the fixing sealant is fully cured.

### FIELD OF THE INVENTION

The present invention relates to a structure and method for connecting a junction box to a solar cell module, and more particularly to a method in which at least one support pin is used to assist in the connection of a junction box to a solar cell module.

### BACKGROUND OF THE INVENTION

Solar power has now been widely applied in people's daily life. Typical examples of environment-friendly application of solar power include solar energy water heaters, solar energy street lamps, and even grid-connected solar generating systems. With the grid-connected solar generating systems, a power company can integrate regular utility power with the solar power generated by individual solar cell modules for distributing to users in a large region. Following the increased solar cell efficiency, the reduced solar cell cost, and the rising awareness of environmental protection, the solar energy industry is now ready to boom with hopeful growth in the future.

A junction box is one of the most important components in a solar cell module. Power generated by individual solar cells is collected at the junction box before being output. Without the junction box, the solar cell module would not be able to work properly to achieve the power generation function thereof and would also have the problem of safety in use.

FIG. 1 is a schematic side view of a first conventional structure for connecting junction box to solar cell module, and FIG. 2 is a sectional view taken along line A-A′ of FIG. 1. As shown, the first conventional connecting structure includes a solar cell module 10, a junction box 12, and a layer of fixing sealant 14 externally applied on one end surface of the solar cell module 10. The junction box 12 is fixed to the end surface of the solar cell module 10 via the layer of fixing sealant 14.

With the above-described first conventional connecting structure, the junction box is secured to the solar cell module via the fixing sealant externally applied on the end surface of the solar cell module. Since the fixing sealant requires a period of time to cure, the junction box tends to separate from the solar cell module before the fixing sealant is fully cured. Thus, with the first conventional connecting structure, a lot of time and labor will be consumed to connect the junction box to the solar cell module.

To overcome the problem in the first conventional connecting structure, there is developed a second conventional connecting structure for connecting a junction box to a solar cell module. Please refer to FIG. 3, in which a conventional junction box 20 is shown. The junction box 20 includes a plurality of connecting tabs 200 and a plurality of conductive plates 202 serving as electrodes, both being fixed to a solar cell module (not shown). In the second conventional connecting structure, the junction box 20 would not be able to be connected to the solar cell module if it has a height larger than an overall thickness of the solar cell module. Further, the connecting tabs 200 are connected to the solar cell module in a compressing process thereof, and the junction box 20 and the connecting tabs 200 thereof are made of a plastic material that must be able to resist the high temperature in the compressing process. This would inevitably increase the manufacturing cost of the junction box.

To overcome the above problem, there is further developed a third conventional connecting structure is for connecting a junction box to a solar cell module. Please refer to FIGS. 4 and 5, in which another conventional junction box 30 is shown. The junction box 30 includes a substantially U-shaped leg 300 extended from a bottom thereof for fixedly connecting to a glass layer of the solar cell module, so as to increase a contact area between the junction box 30 and the solar cell module. In this case, the junction box 30 must have a customized thickness matching that of the glass layer of the solar cell module. However, the increased thickness of the junction box 30 due to the specially shaped leg 300 would result in an increased manufacturing cost of the junction box.

### SUMMARY OF THE INVENTION

A primary object of the present invention is to provide a structure for connecting junction box to solar cell module. The connecting structure includes a solar cell module, a junction box, and at least one support pin. The support pin includes a plug section for plugging in and accordingly holding to a socket section provided on the junction box, a support section for embedding in laminated layers of the solar cell module, and a stop section for internally pressing against an end surface of the solar cell module.

Another object of the present invention is to provide a method for connecting junction box to solar cell module. The connecting method includes the steps of providing a socket section on a junction box; designing a support pin having at least a plug section, a stop section and a support section, so that the plug section has a configuration suitable for detachably plugging in and holding to the socket section of the junction box; embedding the support section of the support pin a plurality of laminated layers of the solar cell module during a laminating process thereof; and internally pressing the stop section of the support pin against an end surface of the solar cell module.

The connecting method further includes the following steps: externally applying a layer of fixing sealant on the stop section of the support pin and the solar cell module at areas for connecting to the junction box with the plug section exposed from the layer of fixing sealant; and finally, plugging the plug section into the socket section of the junction box to connect the junction box to an end surface of the solar cell module.

In the connecting structure and method of the present invention, the support pin is embedded in the laminated layers of the solar cell module for connecting the junction box to the solar cell module. With the support section of the support pin embedded in the laminated layers of the solar cell module, the support section can provide good supporting strength to the junction box. And, with the stop section of the support pin internally pressed against the end surface of the solar cell module, a limiting and lateral supporting effect can be provided to the junction box.

With the above arrangements, the structure and method for connecting junction box to solar cell module according to the present invention has one or more of the following advantages:

(1) The junction box connected to the solar cell module is protected against the risk of separating from the solar cell due to uncured fixing sealant; and

(2) The support pin can be easily designed to have a thickness smaller than that of the solar cell module, and can therefore be advantageously embedded in the solar cell module during the laminating process thereof. And, the junction box will not have an increased thickness due to any specially designed shape thereof.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a schematic side view showing a first conventional structure for connecting junction box to solar cell module;

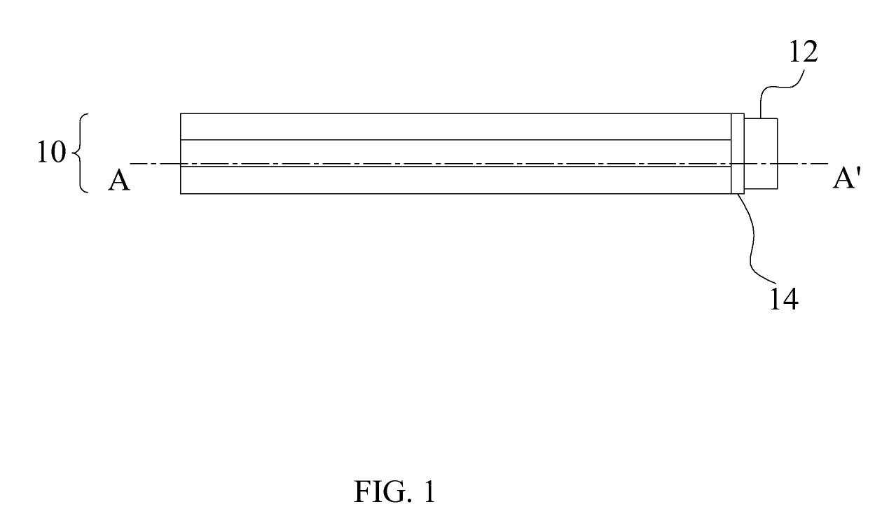

FIG. 2 is a sectional view taken along line A-A′ of FIG. 1;

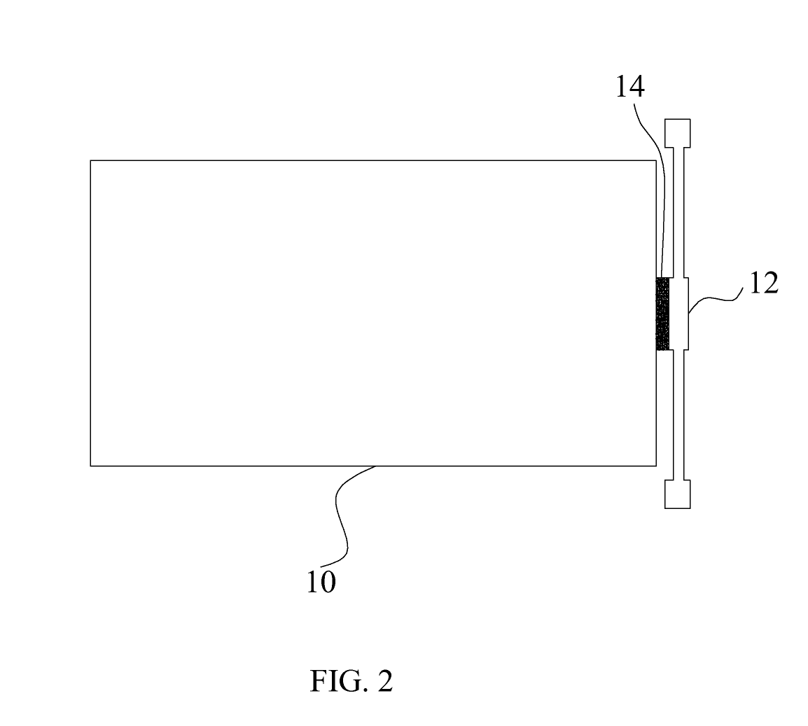

FIG. 3 is a schematic perspective view showing a second conventional structure for connecting junction box to solar cell module;

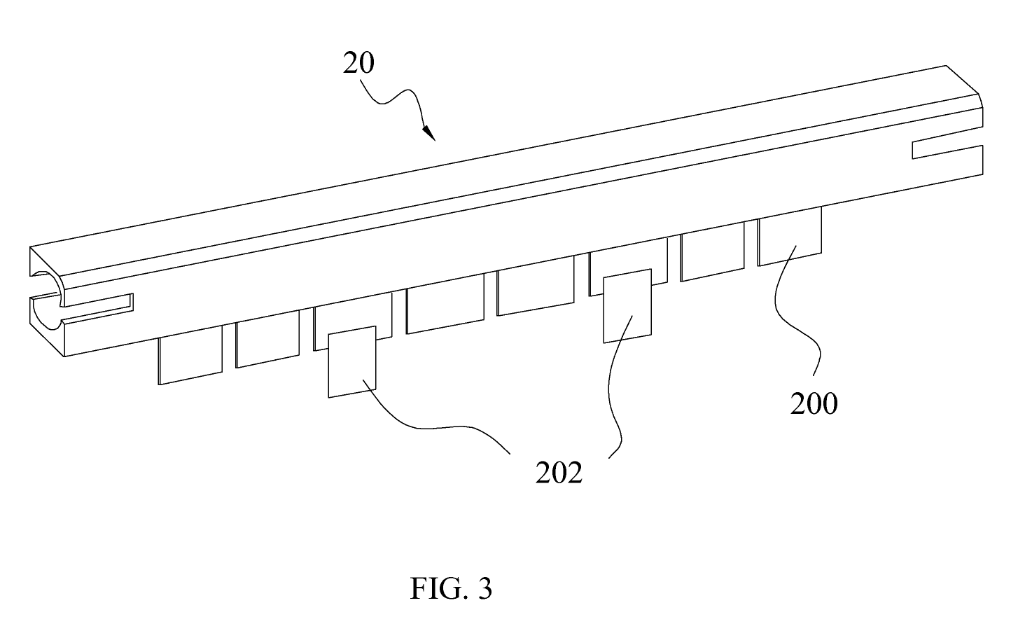

FIG. 4 is a schematic perspective view showing a third conventional structure for connecting junction box to solar cell module;

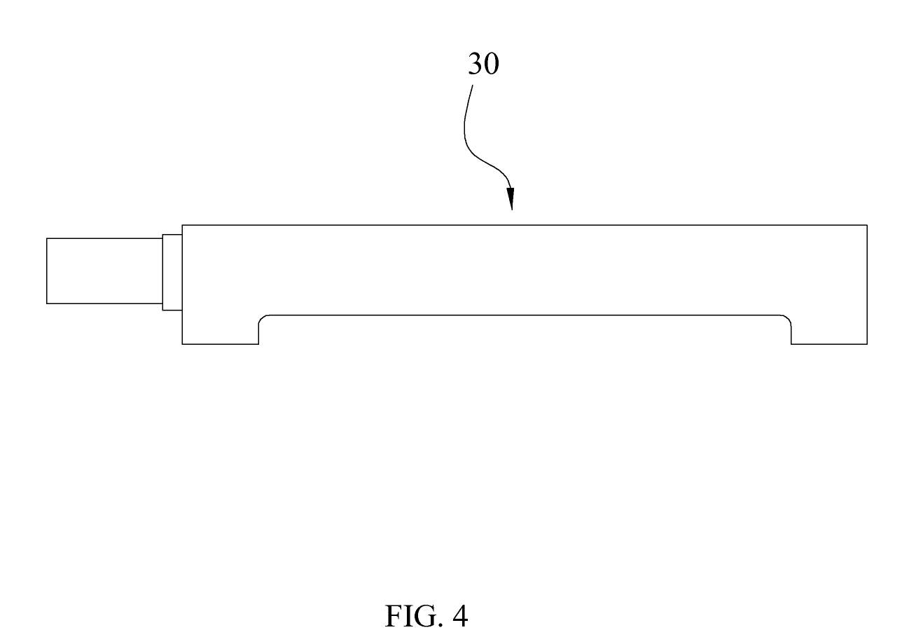

FIG. 5 is a sectional view of FIG. 4;

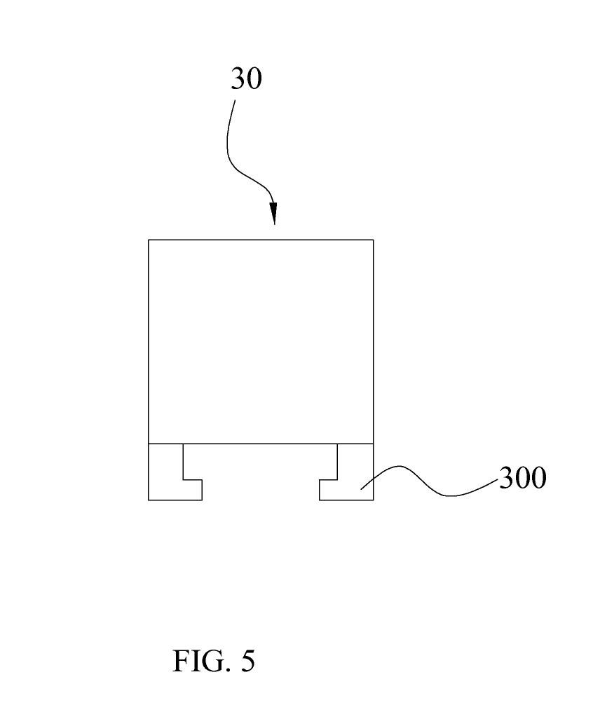

FIG. 6 is a partially exploded schematic side view showing a structure for connecting junction box to solar cell module according to a first embodiment of the present invention;

FIG. 7 is a sectional view taken along line B-B′ of FIG. 6;

FIG. 8 schematically shows the connection of a junction box to the solar cell module via a support pin according to the first embodiment of the present invention;

FIG. 9 schematically shows the connection of two junction boxes to the solar cell module via two support pins according to a second embodiment of the present invention;

FIG. 10 schematically shows the connection of three junction boxes to the solar cell module via three support pins according to a third embodiment of the present invention;

FIG. 11 schematically shows the connection of three junction boxes to the solar cell module via three support pins according to a fourth embodiment of the present invention; and

FIG. 12 is a flowchart showing the steps included in a method for connecting junction box to solar cell module according to the present invention.

### DETAILED DESCRIPTION OF THE PREFERRED EMBODIMENTS

The present invention will now be described with some preferred embodiments thereof and with reference to the accompanying drawings. For the purpose of easy to understand, elements that are the same in the preferred embodiments are denoted by the same reference numerals.

### First Embodiment

### Structure for Connecting One Single Junction Box to a Thin-Film Solar Cell

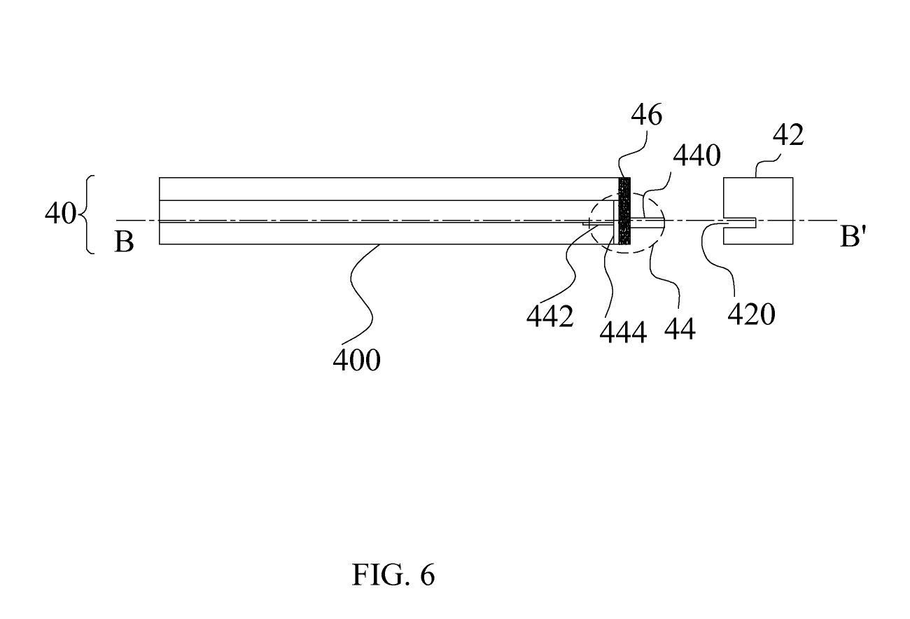

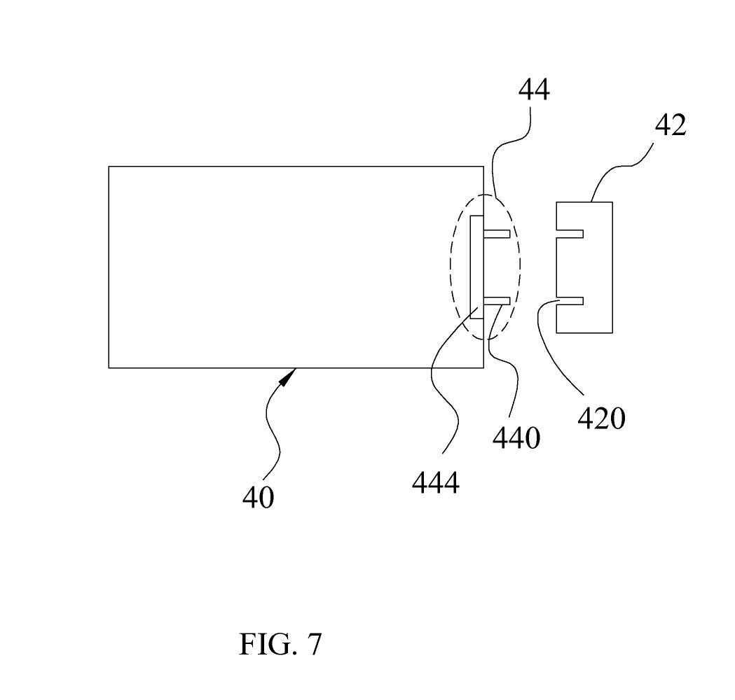

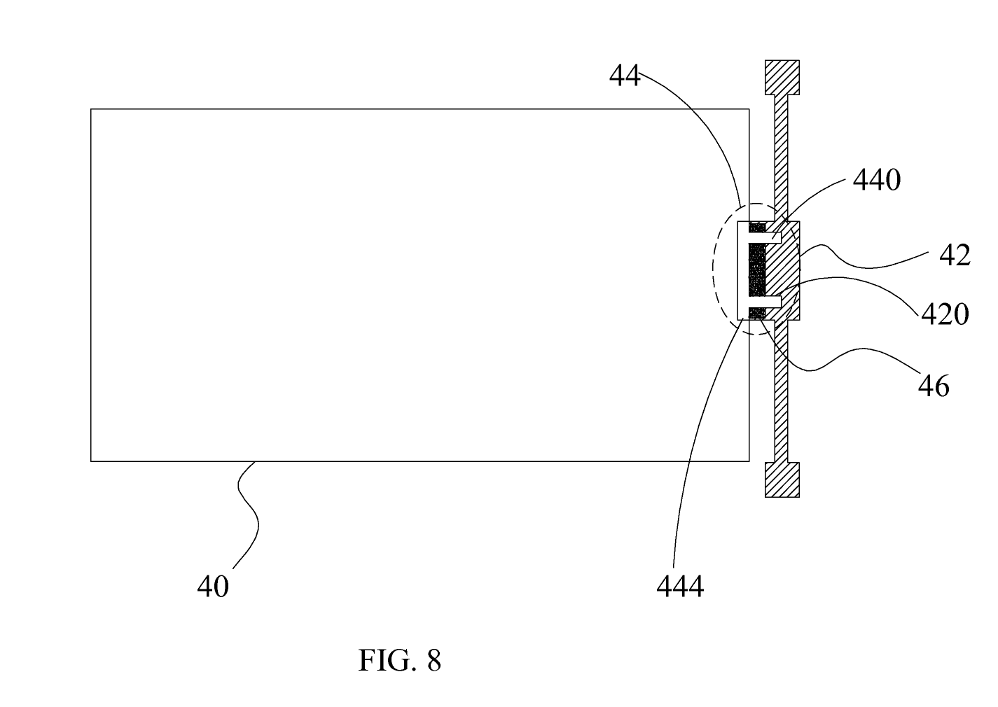

Please refer to FIG. 6 that is a partially exploded schematic view of a structure for connecting junction box to solar cell module according to a first embodiment of the present invention; to FIG. 7 that is a sectional view taken along line B-B′ of FIG. 6; and to FIG. 8 that shows the connection of a junction box to the solar cell module via a support pin according to the first embodiment of the present invention.

In the first embodiment, the connecting structure includes a solar cell module 40, a junction box 42, and at least one support pin 44. The junction box 42 is provided with a socket section 420, and the support pin 44 includes at least a plug section 440, a support section 442, and a stop section 444 located between the plug section 440 and the support section 442. The support section 442 is located in one of a plurality of laminated layers 400 of the solar cell module 40 so as to provide support strength from inside of the solar cell module 40 to the junction box 42. The stop section 444 internally presses against an end surface of the solar cell module 40 to thereby enable a limiting and lateral supporting effect. The plug section 440 of the support pin 44 is exposed from a layer of fixing sealant 46 externally applied on the end surface of the solar cell module 40 for detachably plugging in and accordingly holding to the socket section 420 of the junction box 42. In the first embodiment, the socket section 420 of the junction box 42 includes two sockets, and the plug section 440 of the support pin 44 includes two projections configured corresponding to the two sockets, so that the two projections of the plug section 440 can be fitly plugged in the two sockets of the socket section 420.

### Embodiment 2

### Structure for Connecting Two Junction Boxes to a Thin-Film Solar Cell

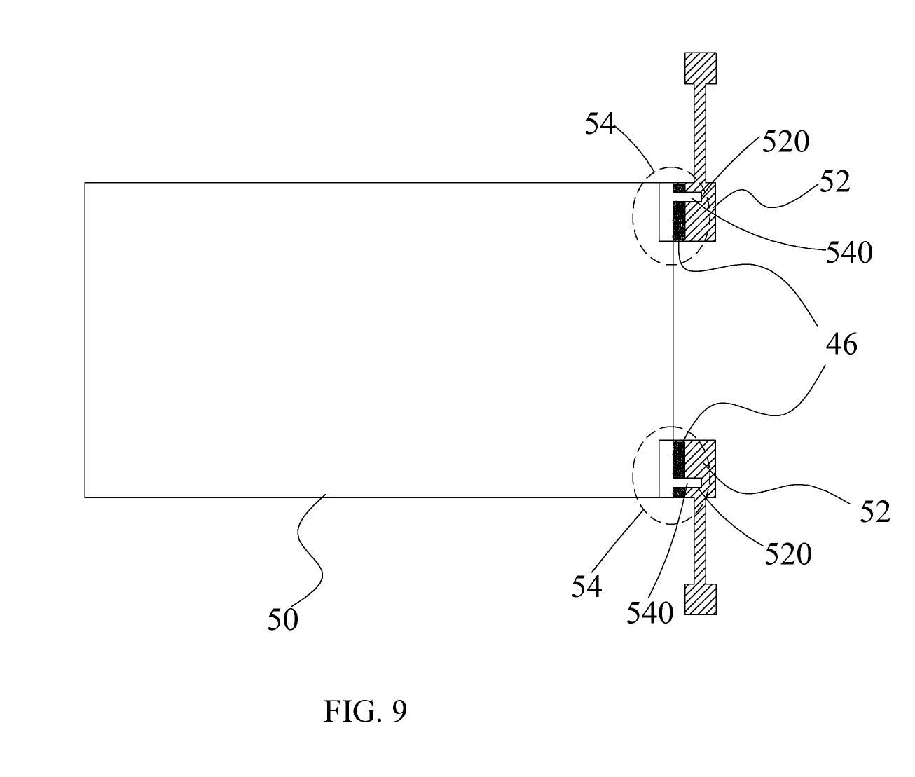

Please refer to FIG. 9 that schematically shows the connection of two junction boxes 52 to a solar cell module 50 via two support pins 54 according to a second embodiment of the present invention. Since the second embodiment is generally structurally similar to the first embodiment, only portions of the second embodiment that are different from the first embodiment will be described herein. In the second embodiment, the solar cell module 50 is provided with two spaced junction boxes 52 and two support pins 54. Each of the two junction boxes 52 is provided with a socket section 520, which includes one single socket. Each of the two support pins 54 includes a plug section 540, which is a projection configured corresponding to the socket of the socket section 520 on the junction box 52, so that the two projections of the two plug sections 540 can be fitly plugged in the two sockets of the two socket sections 520.

### Embodiment 3

### Structure for Connecting Three Junction Boxes to a Thin-Film Solar Cell

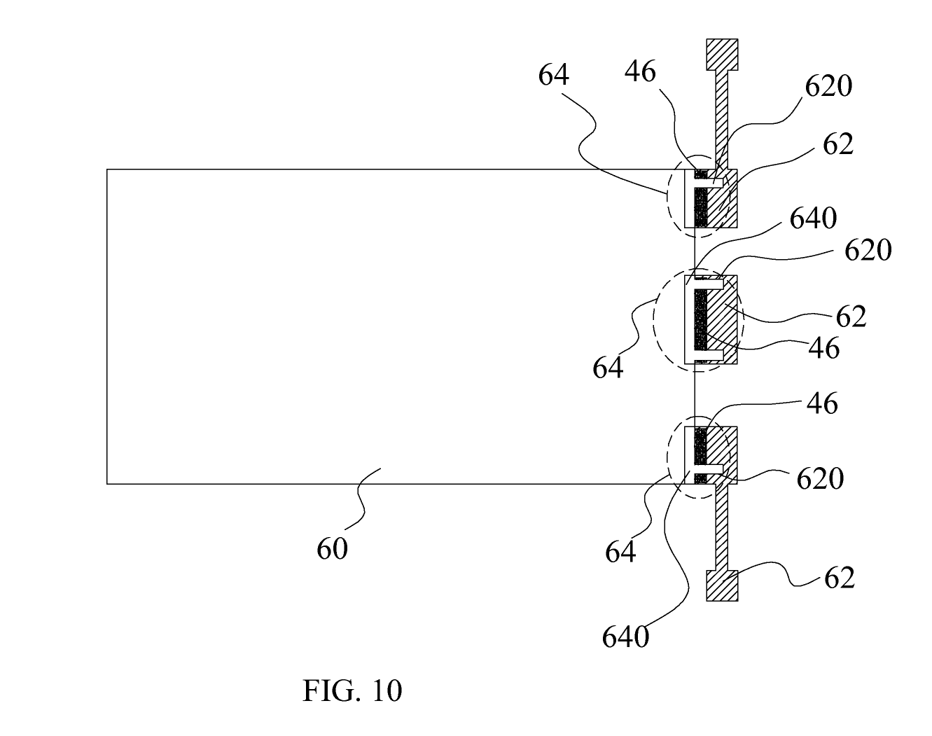

Please refer to FIG. 10 that schematically shows the connection of three junction boxes 62 to a solar cell module 60 via three support pins 64 according to a third embodiment of the present invention. Since the third embodiment is generally structurally similar to the second embodiment, only portions of the third embodiment that are different from the second embodiment will be described herein. In the third embodiment, the solar cell module 60 is provided with three spaced junction boxes 62 and three support pins 64. The three junction boxes 62 and the three support pins 64 are connected to one end surface of the solar cell module 60. A middle one of the three junction boxes 62 is configured the same as the junction box 42 in the first embodiment, and a middle one of the three support pins 64 is configured the same as the support pin 44 in the first embodiment. On the other hand, the other two junction boxes 62 and the other two support pins 64 located at two lateral sides are respectively configured the same as the junction boxes 52 and the support pins 54 in the second embodiment.

### Embodiment 4

### Structure for Connecting Three Junction Boxes to a Mono/Poly Solar Cell Module

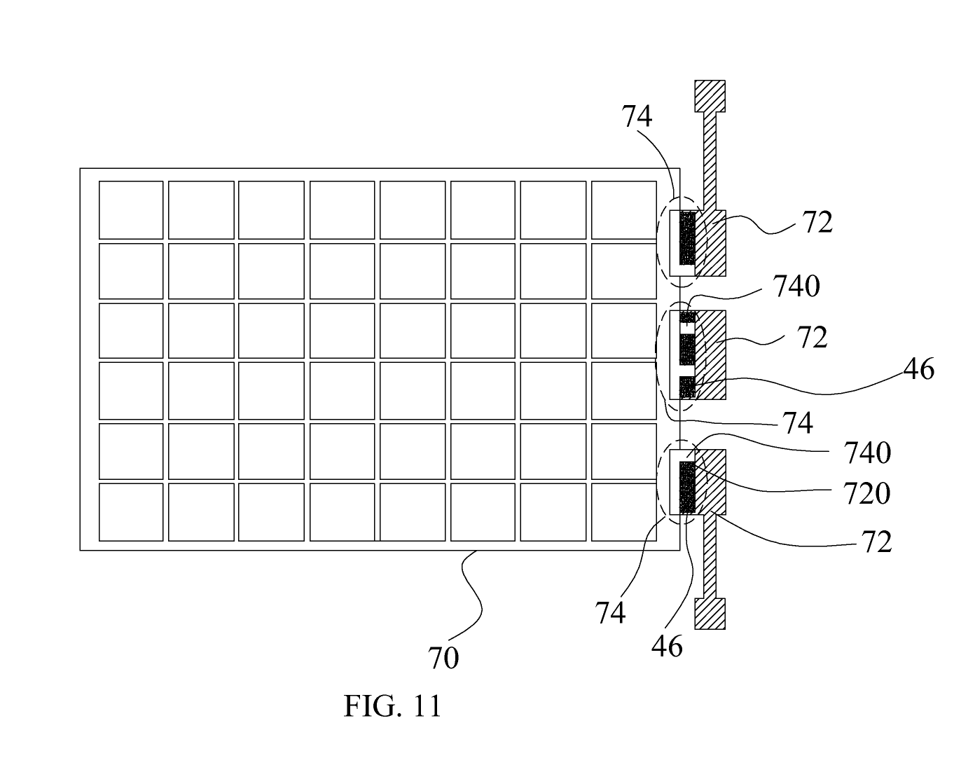

Please refer to FIG. 11 that schematically shows the connection of three junction boxes 72 to a solar cell module 70 via three support pins 74 according to a fourth embodiment of the present invention. Since the fourth embodiment is generally structurally similar to the third embodiment, only portions of the fourth embodiment that are different from the third embodiment will be described herein. In the fourth embodiment, the solar cell module 70 includes a plurality of monocrystalline solar cells 76 serially connected to one another via conductors. The solar cell module 70 is also provided with three junction boxes 72 and three support pins 74, which are respectively configured the same as the junction boxes 62 and the support pins 64 in the third embodiment.

What is to be noted is the support pins are made of an engineering plastic material capable of resisting a high processing temperature more than 100° C., including but not limited to modified polyphenylene ether (PPE) or modified polyphenylene oxide (PPO). Further, the support sections of the support pins are respectively a flat plate with a predetermined length for embedding in the laminated layers of the solar cell module and can therefore provide support strength.

As can be seen from FIG. 6, the laminated layers of the solar cell module include, from top to bottom, a face layer, a photovoltaic (PV) cell layer, and a back layer. The face layer in most cases is a glass layer. The PV cell layer can be a thin film made of a non-silicon crystal material, such as CuInSe₂ (CIS), CuInGaSe₂ (CIGS), or CdTe. Alternatively, the PV cell layer can be formed of a plurality of serially connected silicon wafers. The back layer in most cases is made of a composite material. The face layer, the PV cell layer, and the back layer are compressed and bonded to form a sandwich structure. Thus, in the present invention, the support pin is located on one of the laminated layers. That is, the support pin is located on the PV cell layer or the back layer. In other words, the support pin is embedded between the face layer and the PV cell layer or between the PV cell layer and the back layer.

What is to be further noted is that, in the case of a support pin having a plurality of support sections, the support sections can be separately located on different layers. In other words, while some of the support sections on the same one support pin are embedded between the face layer and the PV cell layer, other support sections thereof can be embedded between the PV cell layer and the back layer, so that support strength can be provided by the support sections at different layers of the solar cell module.

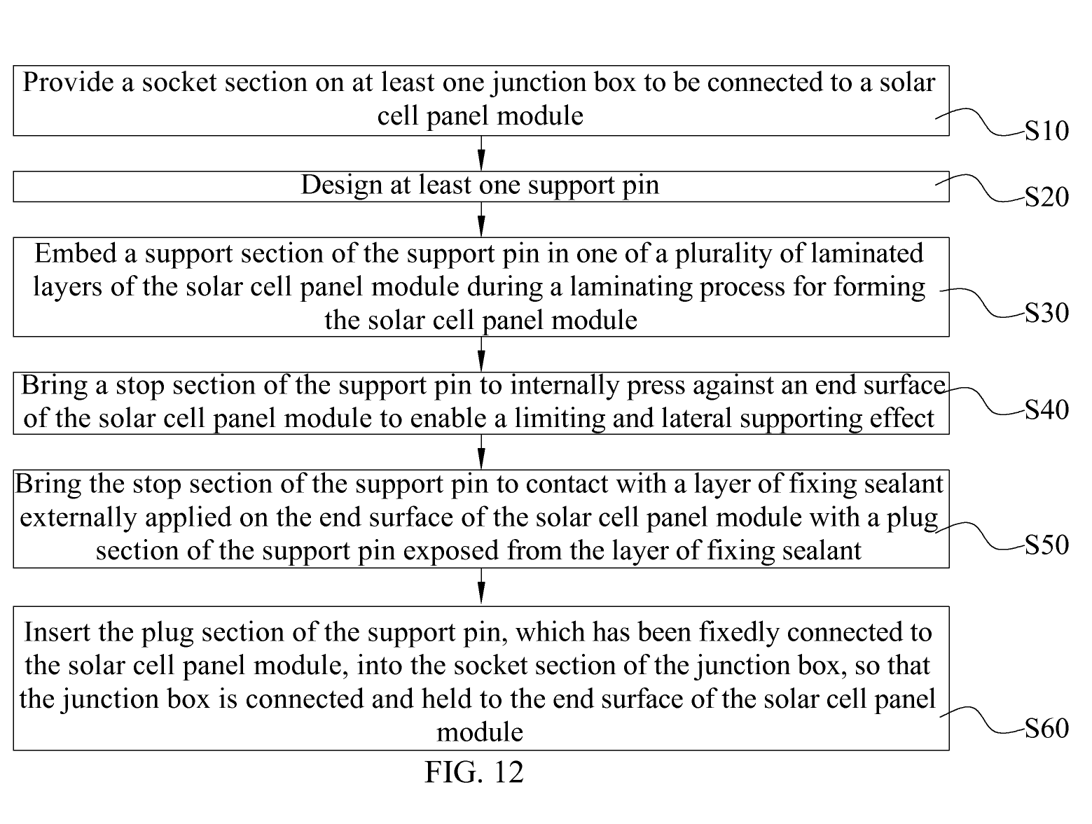

The present invention also provides a method for connecting a junction box to a solar cell module. Please refer to FIG. 12 that is a flowchart showing the steps included in the connecting method according to the present invention. As shown, the steps include:

S10: First, providing a socket section on the junction box to be connected to the solar cell module;

S20: Designing a support pin having at least a plug section, a support section and a stop section; wherein the plug section is configured for detachably plugging in and accordingly holding to the socket section of the junction box;

S30: Then, disposing the support section of the at least one support pin on one of a plurality of laminated layers of the solar panel module during a laminating process for forming the solar cell module, so that the support section is embedded in the laminated layers to provide support strength from inside of the solar cell module to the junction box;

S40: After embedding the support section in the laminated layers of the solar cell module, bringing the stop section to internally press against an end surface of the solar cell module to enable a limiting and lateral supporting effect;

S50: After embedding the support section of the support pin in the solar cell module and finishing the laminating process, bringing the stop section to contact with a layer of fixing sealant externally applied on the end surface of the solar cell module with the plug section exposed from the fixing sealant; and

S60: Finally, after the support pin is held to the solar cell module, plugging the plug section of the support pin into the socket section of the junction box to connect the junction box to the end surface of the solar cell module.

It is noted the support pins are made of an engineering plastic material capable of resisting a high processing temperature more than 100° C., including but not limited to modified polyphenylene ether (PPE) or modified polyphenylene oxide (PPO). Further, the support sections of the support pins are respectively a flat plate with a predetermined length for embedding in the laminated layers of the solar cell module and can therefore provide support strength.

In the present invention, by embedding the support section of the at least one support pin in the laminated layers of the solar cell module, the support section can provide support strength from inside of the solar cell module to the junction box, and the stop section can provide limiting and lateral supporting effect to enable effective support and connection of the junction box to the end surface of the solar cell module, protecting the junction box against the risk of separating from the solar cell module and becoming broken before the fixing sealant is fully cured. Further, since the support pin can be easily designed to have a thickness smaller than that of the solar cell module, the support section can be advantageously embedded in the solar cell module during the laminating process thereof. With these arrangements, the junction boxes will not have an increased thickness due to any specially designed shape thereof.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A method for connecting a junction box to a solar cell module, comprising the following steps:
providing a socket section on the junction box to be connected to the solar cell module;
designing at least one support pin having at least a plug section, a stop section and a support section; and the plug section being configured for detachably plugging in and accordingly holding to the socket section of the junction box;
disposing the support section of the at least one support pin on one of a plurality of laminated layers of the solar panel module during a laminating process for forming the solar cell module, so that the support section is able to provide support strength from inside of the solar cell module to the junction box; after embedding the support section in the laminated layers of the solar cell module, bringing the stop section to internally press against an end surface of the solar cell module to enable a limiting and lateral supporting effect;
after embedding the support section of the support pin in the solar cell module and finishing the laminating process, bringing the stop section to contact with a layer of fixing sealant externally applied on the end surface of the solar cell module with the plug section exposed from the fixing sealant; and
plugging the plug section of the support pin, which has been held to the solar cell module, into the socket section of the junction box to connect the junction box to the end surface of the solar cell module.

2. The method for connecting junction box to solar cell module as claimed in claim 1, wherein the support pin is made of an engineering plastic material having a high processing temperature more than 100° C., and wherein the engineering plastic material is selected from the group consisting of modified polyphenylene ether (PPE) and modified polyphenylene oxide (PPO).

3. A structure for connecting a junction box to solar cell module, comprising:
a solar cell module;
a socket section is positioned on the junction box;
at least one support pin having at least a plug section, a support section and a stop section; the plug section being detachably plugged in and accordingly held to the socket section of the junction box; the support section being embedded in a plurality of laminated layers of the solar cell module and therefore being able to provide support strength from inside of the solar cell module to the junction box; and the stop section being internally pressed against an end surface of the solar cell module to enable a limiting and lateral supporting effect with the plug section exposed from a fixing sealant externally applied on the end surface of the solar cell module.

4. The structure for connecting junction box to solar cell module as claimed in claim 3, wherein the socket section includes two sockets, and the plug section includes two projections configured corresponding to the two sockets.

5. The structure for connecting junction box to solar cell module as claimed in claim 4, wherein two junction boxes are provided, and the support pin is in a number the same as that of the junction boxes.

6. The structure for connecting junction box to solar cell module as claimed in claim 3, wherein the socket section includes a socket, and the plug section includes a projection configured corresponding to the socket.

7. The structure for connecting junction box to solar cell module as claimed in claim 3, wherein the support pin is made of an engineering plastic material having a high processing temperature more than 100° C., and wherein the engineering plastic material is selected from the group consisting of modified polyphenylene ether (PPE) and modified polyphenylene oxide (PPO).

8. The structure for connecting junction box to solar cell module as claimed in claim 3, wherein the support section of the support pin is a flat plate having a predetermined length for embedding in the laminated layers of the solar cell module to provide the support strength.

9. The structure for connecting junction box to solar cell module as claimed in claim 5, wherein the laminated layers of the solar cell module include, from top to bottom, a face layer, a photovoltaic (PV) cell layer, and a back layer.

10. The structure for connecting junction box to solar cell module as claimed in claim 9, wherein the face layer is a glass layer.

11. The structure for connecting junction box to solar cell module as claimed in claim 9, wherein the PV cell layer is a thin film formed of a material selected from the group consisting of CuInSe₂ (CIS), CuInGaSe₂ (CIGS), and CdTe.

12. The structure for connecting junction box to solar cell module as claimed in claim 9, wherein the PV cell layer is formed of a plurality of serially connected silicon wafers.

13. The structure for connecting junction box to solar cell module as claimed in claim 9, wherein the support pin is embedded between the face layer and the PV cell layer.

14. The structure for connecting junction box to solar cell module as claimed in claim 9, wherein the support pin is embedded between the PV cell layer and the back layer.

15. The structure for connecting junction box to solar cell module as claimed in claim 9, wherein the back layer is formed of a composite material.

16. The structure for connecting junction box to solar cell module as claimed in claim 9, wherein the support pin has more than one support section, and a part of the support sections being embedded between the face layer and the PV cell layer while other support sections being embedded between the PV cell layer and the back layer.

17. A structure for connecting a junction box to solar cell module, comprising:
a solar cell module;
a socket section is positioned on the junction box;
a support pin having at least one plug section, a support section and a stop section wherein the plug section being detachably plugged in and accordingly held to the socket section of the junction box; the support section being embedded in a plurality of laminated layers of the solar cell module and therefore being able to provide support strength from inside of the solar cell module to the junction box; and the stop section being internally pressed against an end surface of the solar cell module.

18. The structure for connecting junction box to solar cell module as claimed in claim 17, wherein the socket section includes two sockets, and the plug section includes two projections configured corresponding to the two sockets.

19. The structure for connecting junction box to solar cell module as claimed in claim 17, wherein two junction boxes are provided, and the support pin is in a number the same as that of the junction boxes.

20. The structure for connecting junction box to solar cell module as claimed in claim 17, wherein the socket section includes a socket, and the plug section includes a projection configured corresponding to the socket.
